(19) United States
(12) Patent Application Publication
(10) Pub. No.: US 2024/0379409 A1
(43) Pub. Date: Nov. 14, 2024

(54) SEMICONDUCTOR DEVICE AND METHOD OF FABRICATING THE SAME

(71) Applicant: Samsung Electronics Co., Ltd., Suwon-si (KR)

(72) Inventors: Jaeho Jeon, Suwon-si (KR); Wooseok Park, Suwon-si (KR); Donghoon Hwang, Suwon-si (KR); Myungil Kang, Suwon-si (KR); Kyungho Kim, Suwon-si (KR); Byungho Moon, Suwon-si (KR)

(21) Appl. No.: 18/535,089

(22) Filed: Dec. 11, 2023

(30) Foreign Application Priority Data
May 11, 2023 (KR) 10-2023-0061318

(51) Int. Cl. H01L 21/762; H01L 23/522; H01L 23/528; H01L 29/06; H01L 29/66

(52) U.S. Cl. CPC H01L 21/76229; H01L 23/5226; H01L 23/5286; H01L 29/0696; H01L 29/66553; H01L 29/0673

(57) ABSTRACT

A semiconductor device includes a substrate including an active pattern that is defined by a trench, a device isolation layer in the trench, a first source/drain pattern and a second source/drain pattern on the active pattern, a partition wall between the first and second source/drain patterns, a dam structure and a gate cutting pattern on the device isolation layer, and a gate spacer on a side surface of the gate cutting pattern. The first source/drain pattern is in a recess between the partition wall and the dam structure, and a lower portion of the gate spacer is interposed between the dam structure and the gate cutting pattern. A first thickness of the lower portion of the gate spacer is different from a second thickness of an upper portion of the gate spacer.

### CROSS-REFERENCE TO RELATED APPLICATIONS

This U.S. non-provisional patent application claims priority under 35 U.S.C. § 119 to Korean Patent Application No. 10-2023-0061318, filed on May 11, 2023, in the Korean Intellectual Property Office, the entire contents of which are hereby incorporated herein by reference.

### BACKGROUND

The present disclosure relates to a semiconductor device and a method of fabricating the same, and in particular, to a semiconductor device including a field effect transistor and a method of fabricating the same.

A semiconductor device includes an integrated circuit composed of metal-oxide-semiconductor field-effect transistors (MOS-FETs). To meet an increasing demand for a semiconductor device with a small pattern size and a reduced design rule, the MOS-FETs may be aggressively scaled down. The scale-down of the MOS-FETs may lead to deterioration in operational properties of the semiconductor device. A variety of studies are being conducted to overcome technical limitations associated with the scale-down of semiconductor devices and to realize semiconductor devices with high performance.

### SUMMARY

An embodiment of the inventive concept may provide a semiconductor device with improved reliability characteristics and an increased integration density.

An embodiment of the inventive concept may provide a method of fabricating a semiconductor device with improved reliability characteristics and an increased integration density.

According to an embodiment of the inventive concept, a semiconductor device may include a substrate including an active pattern that is defined by a trench, a device isolation layer in the trench, a first source/drain pattern and a second source/drain pattern on the active pattern, a partition wall between the first and second source/drain patterns, a dam structure and a gate cutting pattern on the device isolation layer, and a gate spacer on a side surface of the gate cutting pattern. The first source/drain pattern may be in a recess between the partition wall and the dam structure, and a lower portion of the gate spacer may be interposed between the dam structure and the gate cutting pattern. A first thickness of the lower portion of the gate spacer may be different from a second thickness of an upper portion of the gate spacer.

According to an embodiment of the inventive concept, a semiconductor device may include a substrate including an active pattern that is defined by a trench, a device isolation layer in the trench, a first channel pattern and a second channel pattern on the active pattern, a partition wall between the first and second channel patterns, a gate electrode on the first and second channel patterns, and a gate cutting pattern on the device isolation layer. The gate cutting pattern may extend into the gate electrode, and the first channel pattern may include a plurality of semiconductor patterns, which are spaced apart from each other in a stack. Each of the semiconductor patterns may have a first side surface and a second side surface, which are opposite to each other. The first side surface may be connected to the partition wall, and the gate cutting pattern is on the second side surface.

According to an embodiment of the inventive concept, a semiconductor device may include a substrate including a first active pattern and a second active pattern, a device isolation layer in a trench between the first and second active patterns, a first source/drain pattern and a second source/drain pattern provided on the first active pattern, a third source/drain pattern and a fourth source/drain pattern provided on the second active pattern, the first and third source/drain patterns having a first conductivity type, the second and fourth source/drain patterns having a second conductivity type, the first source/drain pattern being adjacent to the third source/drain pattern, a first partition wall and a second partition wall on the first and second active patterns, respectively, the first partition wall being interposed between the first and second source/drain patterns, the second partition wall being interposed between the third and fourth source/drain patterns, a dam structure on the device isolation layer, the dam structure being interposed between the first source/drain pattern and the third source/drain pattern, an intermediate insulating pattern on a top surface of the dam structure and top surfaces of the first and second partition walls, an interlayer insulating layer on the intermediate insulating pattern, active contacts that extend into the interlayer insulating layer and are coupled to the first to fourth source/drain patterns, and a first metal layer on the active contacts. The first metal layer may include a power line, and the power line overlaps dam structure in a direction perpendicular to an upper surface of the substrate.

According to an embodiment of the inventive concept, a method of fabricating a semiconductor device may include stacking sacrificial layers and active layers on a substrate to form a stacking layer, patterning the stacking layer and the substrate to form a stacking pattern and an active pattern, respectively, forming a device isolation layer in a trench to define the active pattern, forming a partition wall that extends into the stacking pattern and extends along the active pattern in a first direction, forming a dam structure on the device isolation layer, etching the stacking pattern to form a recess between the partition wall and the dam structure, and forming a source/drain pattern in the recess. The forming of the source/drain pattern may include a selective epitaxial growth process, and the partition wall and the dam structure may inhibit growth of the source/drain pattern in a second direction perpendicular to the first direction.

### BRIEF DESCRIPTION OF THE DRAWINGS

FIGS. 1 to 3 are conceptual diagrams illustrating logic cells of a semiconductor device according to an embodiment of the inventive concept.

FIG. 4 is a plan view illustrating a semiconductor device according to an embodiment of the inventive concept.

FIGS. 5A to 5E are sectional views taken along lines A-A′, B-B′, C-C′, D-D′, and E-E′ of FIG. 4, respectively.

FIG. 6 is a sectional view, which is taken along the line D-D′ of FIG. 4 to illustrate a semiconductor device according to a comparative example.

FIGS. 7A, 7B, 8A, 8B, 9A-9C, 10A-10C, 11A-11C, and 12A-12C are sectional views illustrating a method of fabricating a semiconductor device, according to an embodiment of the inventive concept.

FIG. 13 is a sectional view, which is taken along the line E-E′ of FIG. 4 to illustrate a semiconductor device according to an embodiment of the inventive concept.

FIG. 14 is a sectional view, which is taken along the line D-D′ of FIG. 4 to illustrate a semiconductor device according to an embodiment of the inventive concept.

FIG. 15 is a sectional view, which is taken along the line E-E′ of FIG. 4 to illustrate a semiconductor device according to an embodiment of the inventive concept.

### DETAILED DESCRIPTION

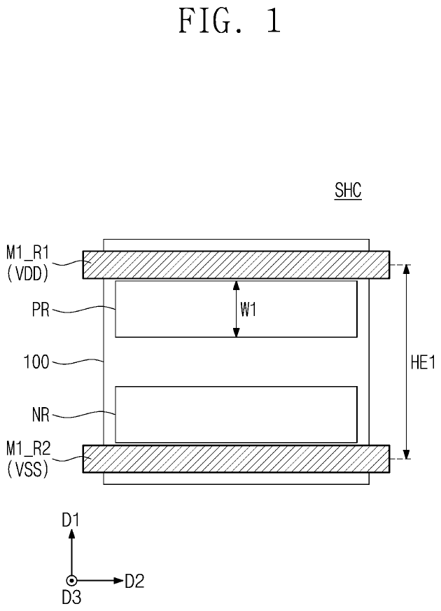

Hereinafter, embodiments will be described in detail with reference to the accompanying drawings. In this description, like reference numerals may indicate like components. It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination. FIGS. 1 to 3 are conceptual diagrams illustrating logic cells of a semiconductor device according to an embodiment of the inventive concept.

Referring to FIG. 1, a single height cell SHC may be provided. In detail, a first power line M1_R1 and a second power line M1_R2 may be provided on a substrate 100. The first power line M1_R1 may be a conduction path, to which a drain voltage VDD (e.g., a power voltage) is provided. The second power line M1_R2 may be a conduction path, to which a source voltage VSS (e.g., a ground voltage) is provided.

The single height cell SHC may be defined between the first power line M1_R1 and the second power line M1_R2. The single height cell SHC may include one PMOSFET region PR and one NMOSFET region NR. In other words, the single height cell SHC may have a CMOS structure provided between the first and second power lines M1_R1 and M1_R2.

Each of the PMOSFET and NMOSFET regions PR and NR may have a first width W1 in a first direction D1. A length of the single height cell SHC in the first direction D1 may be defined as a first height HE1. The first height HE1 may be substantially equal to a distance (e.g., a pitch) between the first and second power lines M1_R1 and M1_R2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting transistors to each other.

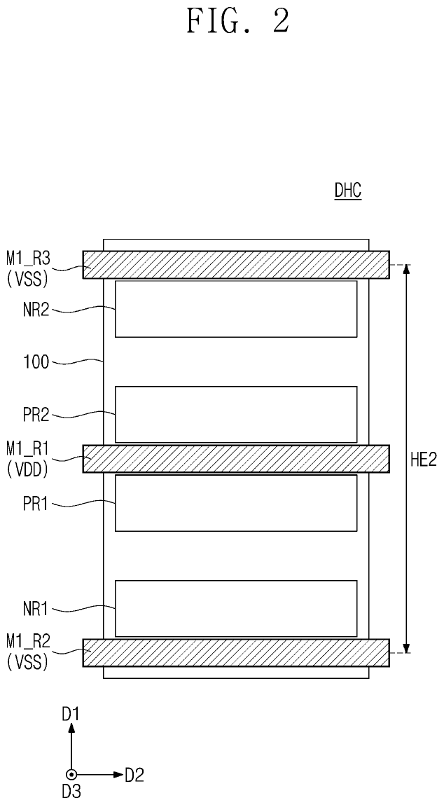

Referring to FIG. 2, a double height cell DHC may be provided. In detail, the first power line M1_R1, the second power line M1_R2, and a third power line M1_R3 may be provided on the substrate 100. The first power line M1_R1 may be disposed between the second power line M1_R2 and the third power line M1_R3. The third power line M1_R3 may be a conduction path, to which the drain voltage VDD is provided.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to the first power line M1_R1. When viewed in a plan view, the first power line M1_R1 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region.

Thus, a channel size of a PMOS transistor of the double height cell DHC may be greater than a channel size of a PMOS transistor of the single height cell SHC previously described with reference to FIG. 1. For example, the channel size of the PMOS transistor of the double height cell DHC may be about two times the channel size of the PMOS transistor of the single height cell SHC. In this case, the double height cell DHC may be operated at a higher speed than the single height cell SHC. In an embodiment, the double height cell DHC shown in FIG. 2 may be defined as a multi-height cell. Although not shown, the multi-height cell may include a triple height cell whose cell height is about three times that of the single height cell SHC.

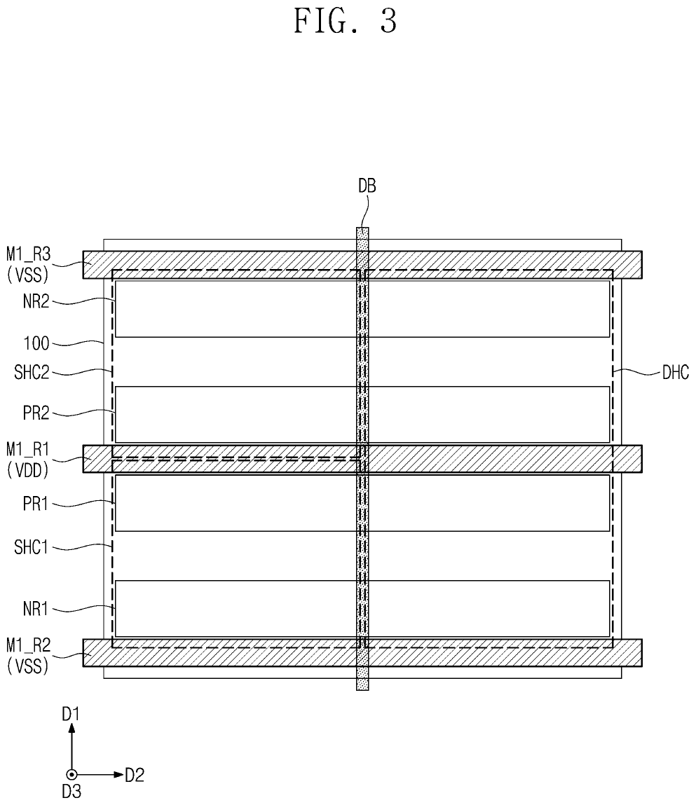

Referring to FIG. 3, a first single height cell SHC1, a second single height cell SHC2, and the double height cell DHC may be two-dimensionally disposed on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in a second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

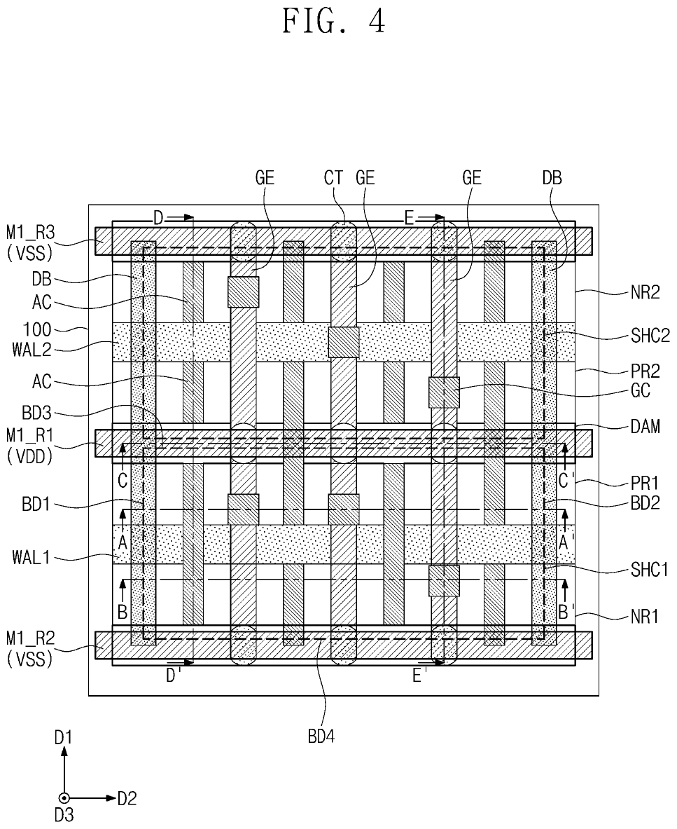

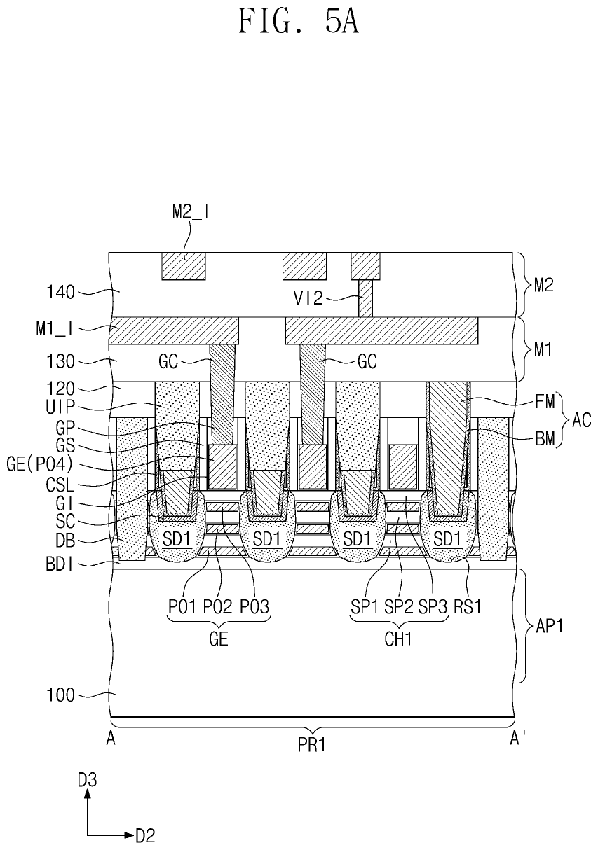

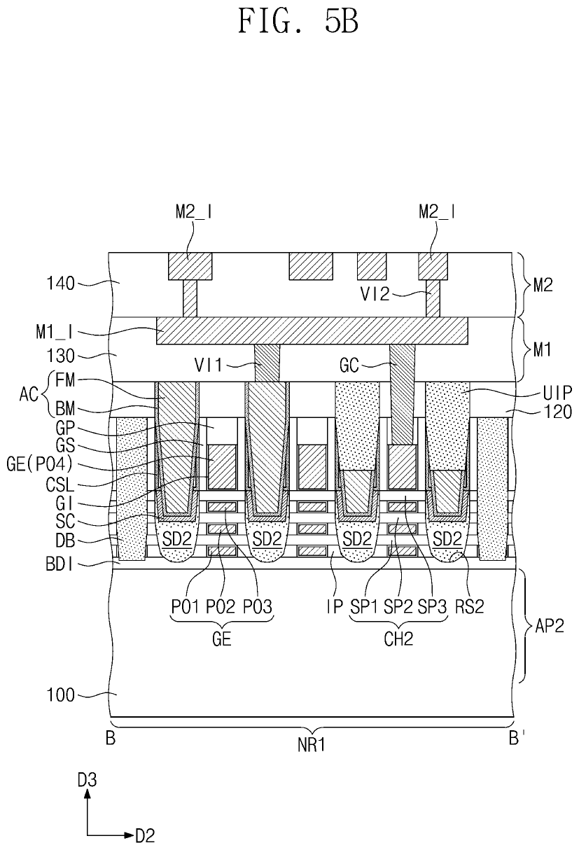

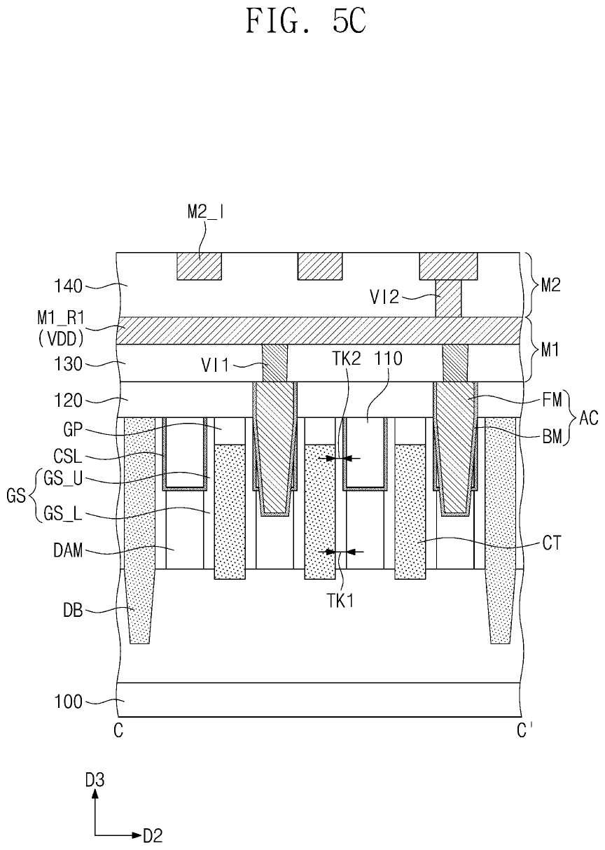

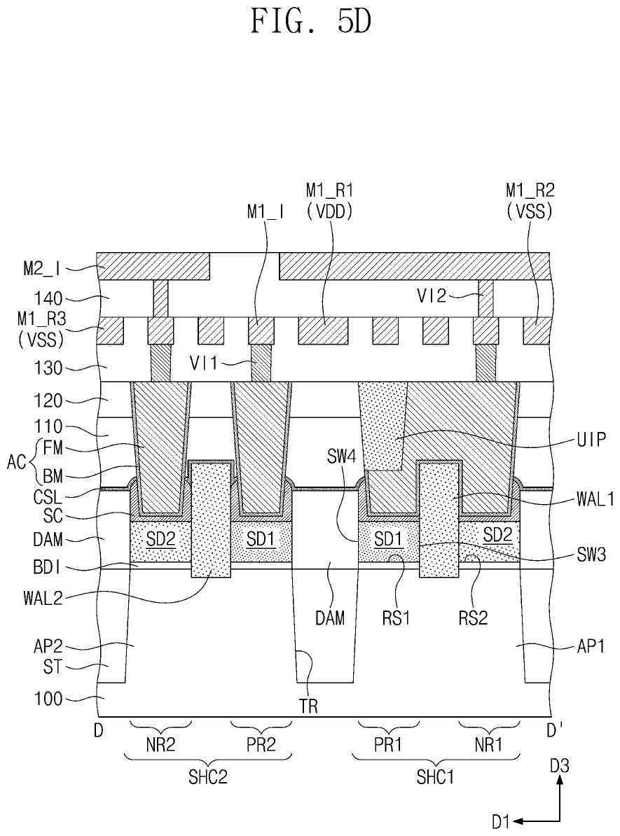

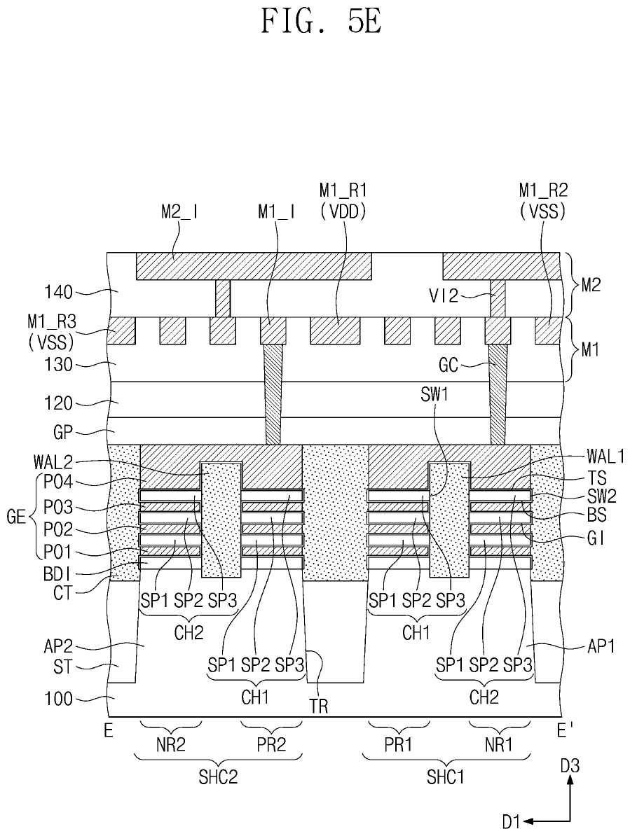

FIG. 4 is a plan view illustrating a semiconductor device according to an embodiment of the inventive concept. FIGS. 5A to 5E are sectional views taken along lines A-A′, B-B′, C-C′, D-D′, and E-E′ of FIG. 4, respectively. FIGS. 4 and 5A to 5E illustrate an example of a detailed structure of the first and second single height cells SHC1 and SHC2 of FIG. 3.

Referring to FIGS. 4 and 5A to 5E, the first and second single height cells SHC1 and SHC2 may be provided on the substrate 100. Logic transistors constituting the logic circuit may be disposed on each of the first and second single height cells SHC1 and SHC2. The substrate 100 may be a semiconductor substrate that is formed of or includes silicon, germanium, silicon germanium, a compound semiconductor material, or the like. In an embodiment, the substrate 100 may be a silicon wafer.

The substrate 100 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR, which is formed in an upper portion of the substrate 100. The first active pattern AP1 may be provided in the first single height cell SHC1. The second active pattern AP2 may be provided in the second single height cell SHC2. The first and second active patterns AP1 and AP2 may extend in the second direction D2. Each of the first and second active patterns AP1 and AP2 may be a vertically-protruding, e.g., D3 direction, portion of the substrate 100 in a cross-sectional view of the semiconductor device.

Each of the first and second active patterns AP1 and AP2 may be an active region of a CMOS structure. Each of the first and second active patterns AP1 and AP2 may include a pair of NMOS and PMOS regions. In an embodiment, the first active pattern AP1 may include the first PMOSFET region PR1 and the first NMOSFET region NR1. The second active pattern AP2 may include the second PMOSFET region PR2 and the second NMOSFET region NR2.

A device isolation layer ST may be provided to be in and at least partially fill the trench TR. The device isolation layer ST may include a silicon oxide layer. The device isolation layer ST may not cover first and second channel patterns CH1 and CH2 to be described below.

A first partition wall WAL1 may be provided on a center region of the first active pattern AP1. The first partition wall WAL1 may have a line-shaped pattern that extends along the first active pattern AP1 or in the second direction D2. The first partition wall WAL1 may be provided to separate the first PMOSFET region PR1 and the first NMOSFET region NR1 of the first active pattern AP1 from each other.

A second partition wall WAL2 may be provided on a center region of the second active pattern AP2. The second partition wall WAL2 may have a line-shaped pattern that extends along the second active pattern AP2 or in the second direction D2. The second partition wall WAL2 may be provided to separate the second PMOSFET region PR2 and the second NMOSFET region NR2 of the second active pattern AP2 from each other.

A first channel pattern CH1 may be provided on the first PMOSFET region PR1 of the first active pattern AP1. A second channel pattern CH2 may be provided on the first NMOSFET region NR1 of the first active pattern AP1. The first partition wall WAL1 may be interposed between the first and second channel patterns CH1 and CH2 of the first active pattern AP1.

Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., a third direction D3).

Each of the first to third semiconductor patterns SP1, SP2, and SP3 may be formed of or include silicon (Si), germanium (Ge), and/or silicon germanium (SiGe). In an embodiment, each of the first to third semiconductor patterns SP1, SP2, and SP3 may be formed of or include crystalline silicon. The first to third semiconductor patterns SP1, SP2, and SP3 may be nanosheets, which are stacked.

Referring back to FIGS. 4 and 5E, the first to third semiconductor patterns SP1, SP2, and SP3 may be directly connected to the first partition wall WAL1. In detail, a first side surface SW1 of each of the first to third semiconductor patterns SP1, SP2, and SP3 may be directly connected to the first partition wall WAL1. The first to third semiconductor patterns SP1, SP2, and SP3 of the first channel pattern CH1 may be connected to a side surface of the first partition wall WAL1, and the first to third semiconductor patterns SP1, SP2, and SP3 of the second channel pattern CH2 may be connected to an opposite side surface of the first partition wall WAL1. A transistor according to the present embodiment may have a fork-sheet structure, in which a plurality of nanosheets are connected to a partition wall.

The first channel pattern CH1 may be provided on the second PMOSFET region PR2 of the second active pattern AP2. The second channel pattern CH2 may be provided on the second NMOSFET region NR2 of the second active pattern AP2. The second partition wall WAL2 may be interposed between the first and second channel patterns CH1 and CH2 of the first active pattern AP1. The first and second channel patterns CH1 and CH2 and the second partition wall WAL2 may be provided to have substantially the same features as the first and second channel patterns CH1 and CH2 and the first partition wall WAL1 on the first active pattern AP1 described above.

Referring back to FIGS. 4 and 5D, a dam structure DAM may be provided between adjacent ones of the active patterns AP1 and AP2. The dam structure DAM may be provided on the device isolation layer ST. The dam structure DAM between the adjacent ones of the active patterns AP1 and AP2 may be extended in the second direction D2, when viewed in a plan view.

Referring back to FIGS. 4 and 5A to 5E, a plurality of first source/drain patterns SD1 may be provided on the first PMOSFET region PR1 of the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the first NMOSFET region NR1 of the first active pattern AP1. A plurality of second recesses RS2 may be formed in an upper portion of the first active pattern AP1. The second source/drain patterns SD2 may be provided in the second recesses RS2, respectively. The second source/drain patterns SD2 may be impurity regions of a second conductivity type (e.g., n-type). The second channel pattern CH2 may be interposed between each pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. In an embodiment, each of the first and second source/drain patterns SD1 and SD2 may have a top surface that is higher in the D3 direction than a top surface of the third semiconductor pattern SP3. In another embodiment, a top surface of at least one of the first and second source/drain patterns SD1 and SD2 may be located at substantially the same level in the D3 direction as the top surface of the third semiconductor pattern SP3.

The first source/drain patterns SD1 may include a semiconductor material (e.g., SiGe) whose lattice constant is greater than that of the substrate 100. Accordingly, each pair of the first source/drain patterns SD1 may exert a compressive stress on the first channel pattern CH1 therebetween. The second source/drain patterns SD2 may be formed of or include the same semiconductor element (e.g., Si) as the substrate 100.

In an embodiment, the first source/drain pattern SD1 may include a buffer layer containing a low concentration of germanium (Ge) and a main layer containing a high concentration of germanium (Ge). The main layer may be provided on the buffer layer. For example, a germanium concentration of the buffer layer may range from 2 at % to 8 at %. A germanium concentration of the main layer may range from 30 at % to 70 at %.

Referring back to FIGS. 4 and 5D, the first partition wall WAL1 may be interposed between the first source/drain pattern SD1 and the second source/drain pattern SD2 on the first active pattern AP1. The first source/drain pattern SD1 may be in direct contact with a side surface of the first partition wall WAL1, and the second source/drain pattern SD2 may be in direct contact with an opposite side surface of the first partition wall WAL1.

Each of the first and second source/drain patterns SD1 and SD2 may be in direct contact with the dam structure DAM. In detail, each of the first and second source/drain patterns SD1 and SD2 may include a third side surface SW3 and a fourth side surface SW4, which are opposite to each other. The third side surface SW3 may be in direct contact with the first partition wall WAL1. The fourth side surface SW4 may be in direct contact with the dam structure DAM. Each of the first and second source/drain patterns SD1 and SD2 may have a bottom surface that is in direct contact with a bottom insulating pattern BDI. According to an embodiment of the inventive concept, the dam structure DAM may inhibit or prevent horizontal, e.g., in the D1 direction, expansion of each of the first and second source/drain patterns SD1 and SD2. Due to the presence of the dam structure DAM, the cell height of the single height cell SHC1 or SHC2 can be reduced, and this may make it possible to increase an integration density of the semiconductor device.

The first source/drain patterns SD1 may be provided on the second PMOSFET region PR2 of the second active pattern AP2. The second source/drain patterns SD2 may be provided on the second NMOSFET region NR2 of the second active pattern AP2. The first and second source/drain patterns SD1 and SD2 and the second partition wall WAL2 may be provided to have substantially the same features as the first and second source/drain patterns SD1 and SD2 and the second partition wall WAL2 on the first active pattern AP1.

Referring back to FIGS. 4 and 5A to 5E, a gate electrode GE may be provided on the first and second channel patterns CH1 and CH2. When viewed in a plan view, the gate electrode GE may be a line- or bar-shaped pattern extending in the first direction D1. In an embodiment, a plurality of gate electrodes GE may be provided. The gate electrodes GE may be arranged at a first pitch in the second direction D2. Each of the gate electrodes GE may be vertically, e.g., D3 direction, overlapped with the first and second channel patterns CH1 and CH2.

The gate electrode GE may include a first inner electrode PO1 interposed between the bottom insulating pattern BDI and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5E, the gate electrode GE may be provided on a top surface TS and a bottom surface BS of each of the first to third semiconductor patterns SP1, SP2, and SP3. In the present embodiment, the gate electrode GE may have a double gate structure on and at least partially covering both the top and bottom surfaces of the channel pattern. The transistor according to the present embodiment may be a three-dimensional field effect transistor (e.g., a fork-sheet FET) in which the gate electrode GE is provided to at least partially surround the channel pattern CH1 or CH2 three-dimensionally.

A gate insulating layer GI may be interposed between the gate electrode GE and the first channel pattern CH1 and between the gate electrode GE and the second channel pattern CH2. The gate insulating layer GI may be on and at least partially cover the top surface TS, the bottom surface BS, and a second side surface SW2 of each of the first to third semiconductor patterns SP1, SP2, and SP3. The gate insulating layer GI on the second side surface SW2 may be in direct contact with a gate cutting pattern CT, which will be described below.

The gate insulating layer GI may include a silicon oxide layer, a silicon oxynitride layer, and/or a high-k dielectric layer. In an embodiment, the gate insulating layer GI may include a silicon oxide layer and a high-k dielectric layer, which are sequentially stacked. The high-k dielectric layer may be formed of or include one or more high-k dielectric materials whose dielectric constants are greater than that of silicon oxide. For example, the high-k dielectric material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

Referring back to FIGS. 4 and 5A to 5E, the first single height cell SHC1 may have a first border BD1 and a second border BD2, which are opposite to each other in the second direction D2. The first and second borders BDI and BD2 may extend in the first direction D1. The first single height cell SHC1 may have a third border BD3 and a fourth border BD4, which are opposite to each other in the first direction D1. The third and fourth borders BD3 and BD4 may extend in the second direction D2.

In an embodiment, the gate cutting patterns CT may be disposed on borders of each of the first and second single height cells SHC1 and SHC2 in the second direction D2. For example, the gate cutting patterns CT may be disposed on the third and fourth borders BD3 and BD4 of the first single height cell SHC1. The gate cutting patterns CT may be arranged at the first pitch along the third border BD3. The gate cutting patterns CT may be arranged at the first pitch along the fourth border BD4. When viewed in a plan view, the gate cutting patterns CT on the third and fourth borders BD3 and BD4 may be disposed to overlap in the D3 direction with the gate electrodes GE, respectively. The gate cutting patterns CT may be formed of or include one or more insulating materials (e.g., silicon oxide and silicon nitride).

The gate electrode GE on the first single height cell SHC1 may be separated from the gate electrode GE on the second single height cell SHC2 by the gate cutting pattern CT. The gate cutting pattern CT may be interposed between the gate electrodes GE, which are placed on the first and second single height cells SHC1 and SHC2 aligned to each other in the first direction D1. That is, the gate electrode GE extending in the first direction D1 may be divided into a plurality of the gate electrodes GE by the gate cutting patterns CT.

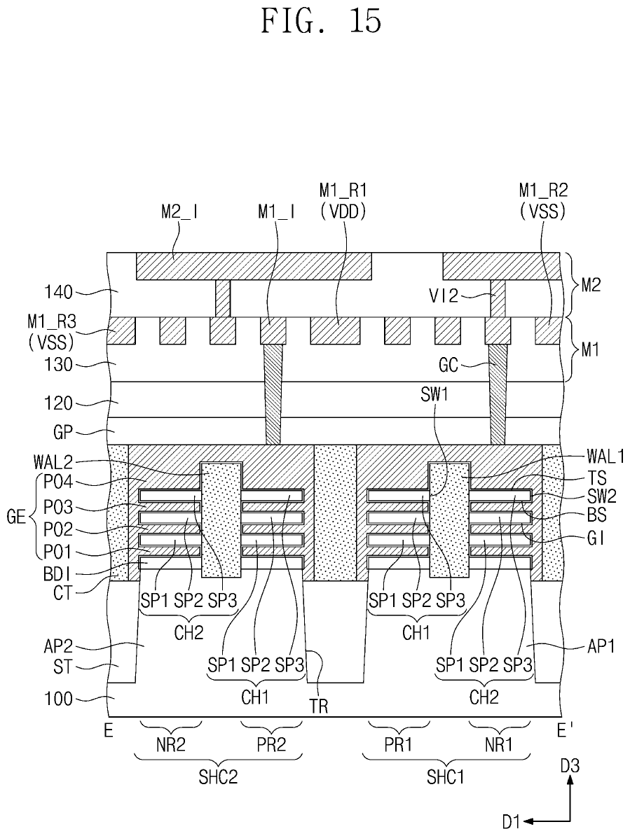

Referring back to FIG. 5E, the gate cutting pattern CT may be formed to be in contact with the second side surface SW2 of each of the first to third semiconductor patterns SP1, SP2, and SP3. In the present embodiment, the gate electrode GE may have a relatively small length. Such a reduction of the length of the gate electrode GE may lead to a reduction of a volume of the gate electrode GE. As a result, a parasitic capacitance between the gate electrode GE and the active contact AC adjacent thereto may be reduced. In addition, a parasitic capacitance between the gate electrode GE and the first and second source/drain patterns SD1 and SD2 adjacent thereto may also be reduced. Due to the reduction of the parasitic capacitance, the semiconductor device may have an increased operation speed and improved electrical characteristics. According to an embodiment of the inventive concept, the single height cell SHC1 or SHC2 may have a relatively small cell height, and in this case, it may be possible to form the gate cutting pattern CT, which is in direct contact with the channel CH1 or CH2. In another embodiment, the gate cutting pattern CT may be formed to be spaced apart from the second side surface SW2 of each of the first to third semiconductor patterns SP1, SP2, and SP3, as will be described with reference to FIG. 15.

Referring back to FIG. 4 and FIGS. 5A to 5E, a pair of gate spacers GS may be respectively disposed on opposite side surfaces of the outer electrode PO4 of the gate electrode GE. The gate spacers GS may extend along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. In an embodiment, the gate spacers GS may be formed of or include SiCN, SiCON, and/or SiN. In another embodiment, the gate spacers GS may be a multi-layered structure, which is formed of or includes at least two different materials selected from SiCN, SiCON, and SiN.

A gate capping pattern GP may be provided on the gate electrode GE. The gate capping pattern GP may extend along the gate electrode GE or in the first direction D1. The gate capping pattern GP may be formed of or include a material having an etch selectivity with respect to first and second interlayer insulating layers 110 and 120, which will be described below. In detail, the gate capping pattern GP may be formed of or include SiON, SiCN, SiCON, and/or SiN.

The gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that includes one or more metallic materials, such as, but not limited to, titanium (Ti), tantalum (Ta), aluminum (Al), tungsten (W) and molybdenum (Mo), and/or nitrogen (N). In an embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may be formed of or include one or more metallic materials, such as, but not limited to, tungsten (W), aluminum (Al), titanium (Ti), and/or tantalum (Ta). For example, the outer electrode PO4 of the gate electrode GE may include the first metal pattern and the second metal pattern on the first metal pattern.

Referring back to FIG. 5B, inner spacers IP may be provided on the first and second NMOSFET regions NR1 and NR2. For example, at least one inner spacer IP may be provided between the second channel pattern CH2 and the second source/drain pattern SD2. The inner spacers IP may be respectively interposed between the first to third inner electrodes PO1, PO2, and PO3 of the gate electrode GE and the second source/drain pattern SD2. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacer IP.

Referring back to FIGS. 4 and 5A to 5E, an intermediate insulating pattern CSL may be provided on the dam structure DAM. The intermediate insulating pattern CSL may be an insulating layer with a constant or conformal thickness. The intermediate insulating pattern CSL may be formed of or include an insulating material different from the dam structure DAM. The intermediate insulating pattern CSL may be formed of or include SiCN, SiCON, and/or SiN. The intermediate insulating pattern CSL may be provided to be directly on and at least partially cover not only the dam structure DAM but also the source/drain pattern SD1 or SD2, the partition wall WAL1 or WAL2, and the gate spacer GS.

Referring back to FIG. 5C, the gate spacer GS may include an upper portion GS_U and a lower portion GS_L. The upper portion GS_U may be at least partially covered with the intermediate insulating pattern CSL. The lower portion GS_L may be at least partially covered with the dam structure DAM. A bottom surface of the lower portion GS_L may be in contact with a top surface of the device isolation layer ST.

A thickness TK2 of the upper portion GS_U of the gate spacer GS may be different from a thickness TK1 of the lower portion GS_L. In an embodiment, the thickness TK1 of the lower portion GS_L may be larger than the thickness TK2 of the upper portion GS_U. This is because the lower portion GS_L is protected by the dam structure DAM and thus is kept thicker than the upper portion GS_U.

Referring back to FIGS. 4 and 5A to 5E, the first interlayer insulating layer 110 may be provided on the intermediate insulating pattern CSL. The first interlayer insulating layer 110 may be on and at least partially cover the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 to be on and at least partially cover the gate capping pattern GP. A third interlayer insulating layer 130 may be provided on the second interlayer insulating layer 120. A fourth interlayer insulating layer 140 may be provided on the third interlayer insulating layer 130. In an embodiment, at least one of the first to fourth interlayer insulating layers 110, 120, 130, and 140 may include a silicon oxide layer.

A pair of division structures DB may be provided at both sides of each of the first and second single height cells SHC1 and SHC2 to be opposite to each other in the second direction D2. For example, a pair of the division structures DB may be respectively provided on the first and second borders BDI and BD2 of the first single height cell SHC1. The division structure DB may extend in the first direction D1 to be parallel to the gate electrodes GE. A pitch between the division structure DB and the gate electrode GE adjacent thereto may be equal to the first pitch.

The division structure DB may extend to the bottom insulating pattern BDI to penetrate or extend into the gate capping pattern GP and the gate electrode GE. The division structure DB may penetrate or extend into an upper portion of the device isolation layer ST between the active patterns AP1 and AP2. The division structure DB may electrically separate an active region of each of the first and second single height cells SHC1 and SHC2 from an active region of a neighboring cell.

Active contacts AC may be provided to penetrate or extend into the first and second interlayer insulating layers 110 and 120 and to be electrically connected to the first and second source/drain patterns SD1 and SD2, respectively. A pair of the active contacts AC may be respectively provided at both sides of the gate electrode GE. When viewed in a plan view, the active contact AC may be a bar-shaped pattern that extends in the first direction D1.

The active contact AC may be a self-aligned contact. For example, the active contact AC may be formed by a self-alignment process using the gate capping pattern GP and the gate spacer GS. For example, the active contact AC may be on and at least partially cover at least a portion of the side surface of the gate spacer GS. Although not shown, the active contact AC may be provided to be on and at least partially cover a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include titanium silicide, tantalum silicide, tungsten silicide, nickel silicide, and/or cobalt silicide.

Referring back to FIG. 5D, at least one active contact AC on the first single height cell SHC1 may be configured to electrically connect the first source/drain pattern SD1 and the second source/drain pattern SD2 on the first active pattern AP1 to each other. The active contact AC may be connected in common to the first source/drain pattern SD1 and the second source/drain pattern SD2 on the first active pattern AP1.

The active contact AC may include a barrier metal BM and a fill metal FM on the barrier metal BM. The barrier metal BM may be provided to at least partially enclose all surfaces of the fill metal FM, except for its top surface. For example, the fill metal FM may be formed of or include molybdenum, tungsten, ruthenium, cobalt, and/or vanadium. The barrier metal BM may include a metal nitride layer. The metal nitride layer may be formed of or include titanium nitride (TiN), tantalum nitride (TaN), tungsten nitride (WN), nickel nitride (NiN), cobalt nitride (CON), and/or platinum nitride (PtN).

Referring back to FIGS. 4 and 5A to 5E, gate contacts GC may be provided to penetrate or extend into the third interlayer insulating layer 130, the second interlayer insulating layer 120, and the gate capping pattern GP and to be electrically connected to the gate electrodes GE, respectively. When viewed in a plan view, two gate contacts GC on the first single height cell SHC1 may overlap the first PMOSFET region PR1 in the D3 direction (e.g., see FIG. 5A). When viewed in a plan view, one gate contact GC on the first single height cell SHC1 may overlap the first NMOSFET region NR1 in the D3 direction (e.g., see FIG. 5B).

The gate contact GC may be freely disposed on the gate electrode GE, without any restrictions on its position. For example, the gate contacts GC on the second single height cell SHC2 may be disposed on the second PMOSFET region PR2, the second NMOSFET region NR2, and the second partition wall WAL2, respectively (e.g., see FIG. 4).

In an embodiment, referring to FIGS. 5A and 5B, an upper portion of the active contact AC adjacent to the gate contact GC may be at least partially filled with an upper insulating pattern UIP. A bottom surface of the upper insulating pattern UIP may be lower than a bottom surface of the gate contact GC in the D3 direction. In other words, a top surface of the active contact AC adjacent to the gate contact GC may be formed at a level, which is lower than the bottom surface of the gate contact GC in the D3 direction, by the upper insulating pattern UIP. Accordingly, it may be possible to inhibit or prevent the gate contact GC and the active contact AC, which are adjacent to each other, from being in contact with each other and thereby to prevent or reduce the likelihood of a short circuit issue from occurring therebetween.

A first via VI1 may be provided on the active contact AC. The first via VI1 may have a top surface that is located at substantially the same level as the top surface of the gate contact GC in the D3 direction. In an embodiment, the first via VI1 and the gate contact GC may be formed at the same time using the same process. The first via VI1 and the gate contact GC may be formed of or include the same material.

The gate contact GC may not have the barrier metal, unlike the active contact AC. The gate contact GC may be formed of a single metal layer. The gate contact GC may be formed of or include molybdenum, tungsten, ruthenium, cobalt, and/or vanadium. The first via VI1 may not have the barrier metal, like the gate contact GC. The first via VI1 may be formed of or include the same metallic material as the gate contact GC.

A first metal layer M1 may be provided in the third interlayer insulating layer 130. For example, the first metal layer M1 may include the first power line M1_R1, the second power line M1_R2, the third power line M1_R3, and first interconnection lines M1_I. The interconnection lines M1_R1, M1_R2, M1_R3, and M1_I of the first metal layer M1 may extend in the second direction D2 to be parallel to each other.

In detail, the first and second power lines M1_R1 and M1_R2 may be provided on the third and fourth borders BD3 and BD4 of the first single height cell SHC1, respectively. The first power line M1_R1 may extend along the third border BD3 and in the second direction D2. The second power line M1_R2 may extend along the fourth border BD4 and in the second direction D2.

The first interconnection lines M1_I of the first metal layer M1 may be arranged at a second pitch in the first direction D1. The second pitch may be smaller than the first pitch. A linewidth of each of the first interconnection lines M1_I may be smaller than a linewidth of each of the first to third power lines M1_R1, M1_R2, and M1_R3.

The active contact AC and the interconnection line of the first metal layer M1 may be electrically connected to each other through the first via VI1. The gate electrode GE and the interconnection line of the first metal layer M1 may be electrically connected to each other through the gate contact GC.

The interconnection line of the first metal layer M1 and the first via VI1 thereunder may be formed by separate processes. For example, the interconnection line and the first via VI1 of the first metal layer M1 may be independently formed by respective single damascene processes. The semiconductor device according to the present embodiment may be fabricated using a sub-20 nm process.

A second metal layer M2 may be provided in the fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. In other words, the second interconnection lines M2_I may extend in the first direction D1 and parallel to each other.

The second metal layer M2 may further include second vias VI2, which are respectively provided below the second interconnection lines M2_I. The interconnection lines of the first and second metal layers M1 and M2 may be electrically connected to each other through the second via VI2. The interconnection line of the second metal layer M2 and the second via VI2 thereunder may be formed together by a dual damascene process.

The interconnection lines of the first metal layer M1 may be formed of or include a conductive material that is the same as or different from those of the second metal layer M2. For example, the interconnection lines of the first and second metal layers M1 and M2 may be formed of or include one or more metallic materials (e.g., copper, ruthenium, aluminum, tungsten, molybdenum, and/or cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

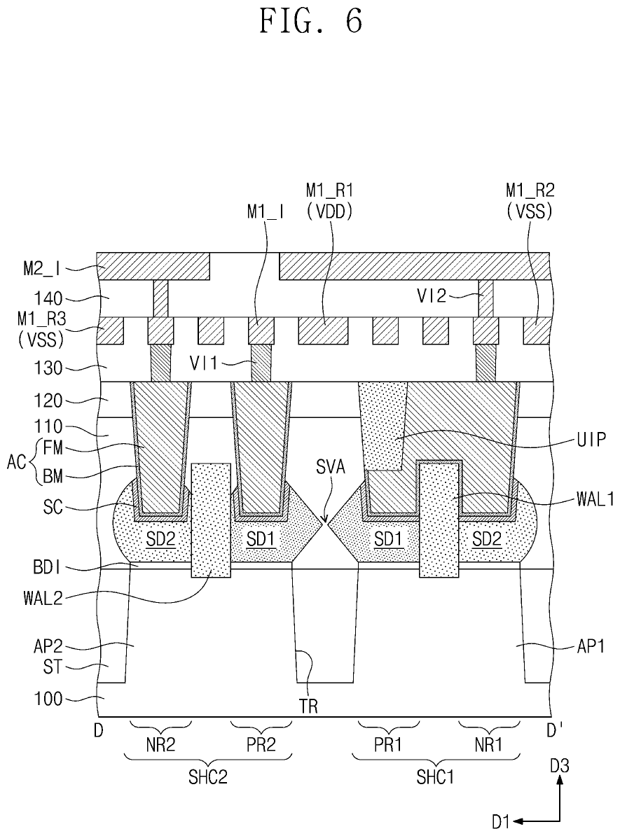

FIG. 6 is a sectional view, which is taken along the line D-D′ of FIG. 4 to illustrate a semiconductor device according to a comparative example. As shown in FIG. 6, the dam structure DAM previously described with reference to FIGS. 4 and 5D is not provided in the semiconductor device according to the comparative example.

The first source/drain pattern SD1 on the first active pattern AP1 may be adjacent to the first source/drain pattern SD1 on the second active pattern AP2 in the first direction D1. If the dam structure DAM is not provided, the first source/drain pattern SD1 may be grown to have a horizontally, e.g., D1 direction, expanded structure. This is because, during a selective epitaxial growth (SEG) process, the growth rate of the first source/drain pattern SD1 depends on its crystalline direction of its exposed surface.

In the case where a width of the first source/drain pattern SD1 in the first direction D1 is increased, there may be a short vulnerable area SVA between the first source/drain patterns SD1, which are adjacent to each other. If the first source/drain patterns SD1 are in contact with each other, the semiconductor device cannot be normally operated.

Thus, for the semiconductor device according to the comparative example, a distance between the active patterns AP1 and AP2 may be increased. This may lead to an increase of the cell height of the single height cell SHC1 or SHC2 in the first direction D1. That is, there may be a difficulty in increasing an integration density of the semiconductor device according to the comparative example.

By contrast, for the semiconductor device according to an embodiment of the inventive concept, the dam structure DAM may be used to inhibit or prevent the horizontal, e.g., D1 direction, growth of the source/drain pattern SD1 or SD2, as previously described with reference to FIGS. 4 and 5D. Thus, even when the distance between the active patterns AP1 and AP2 is reduced, the short vulnerable area SVA of FIG. 6 may not occur. In this case, the cell height of the single height cell SHC1 or SHC2 can be reduced, and this may make it possible to increase the integration density of the semiconductor device.

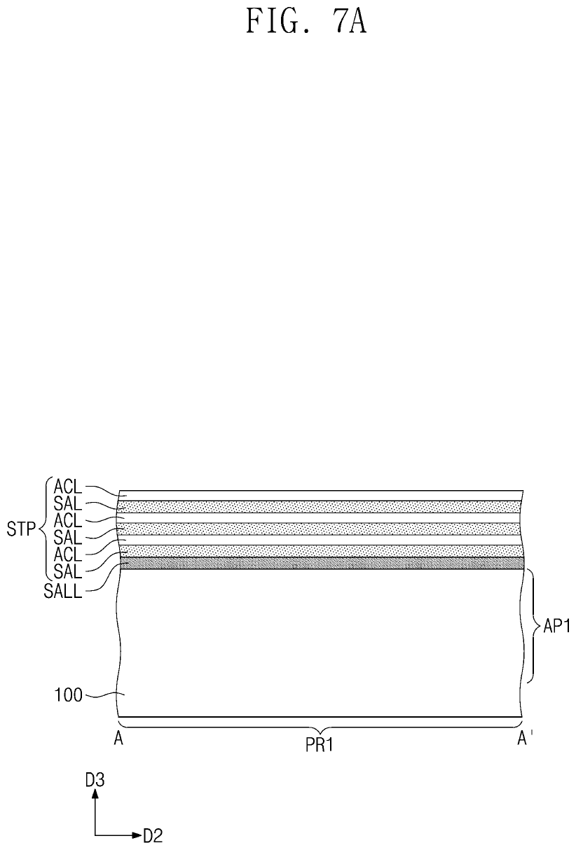

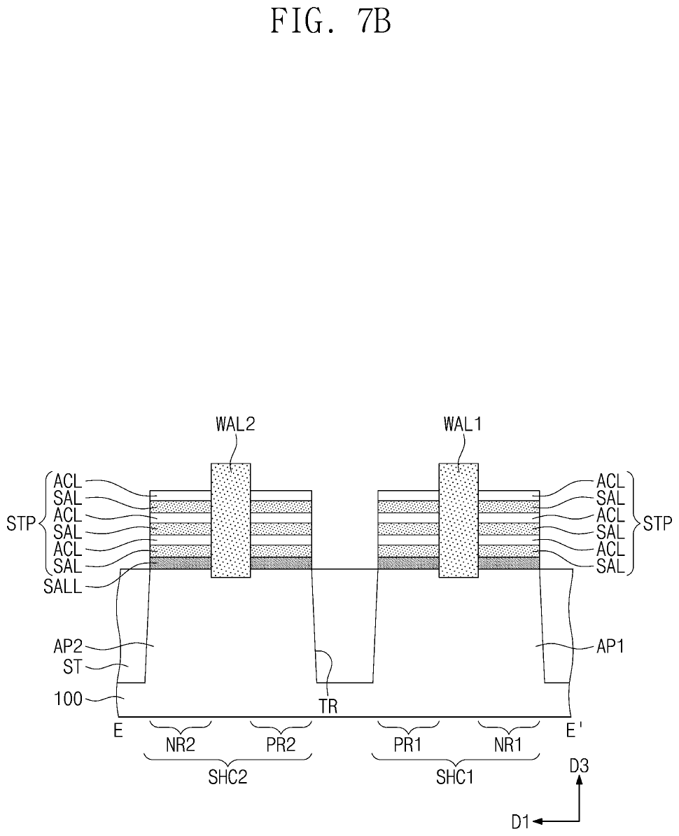

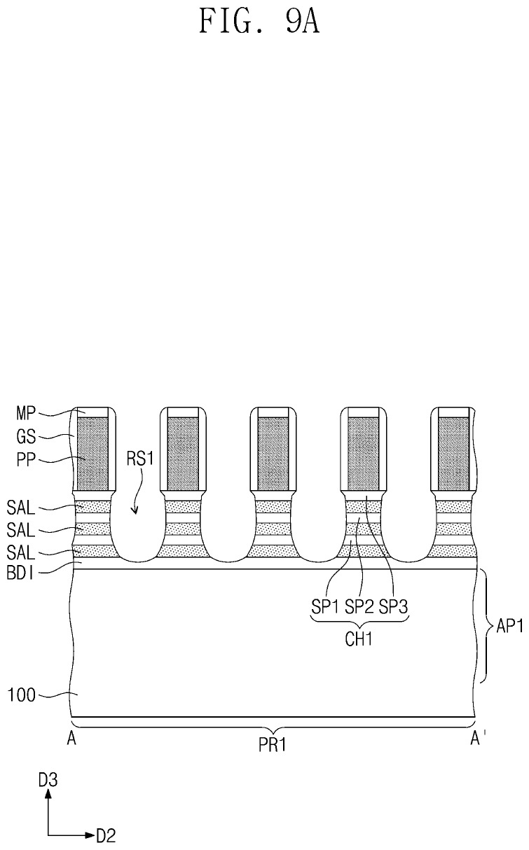

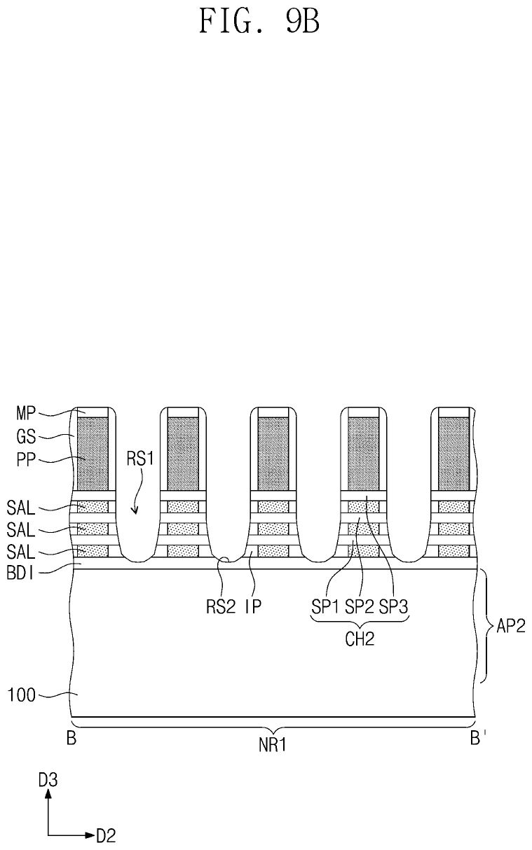

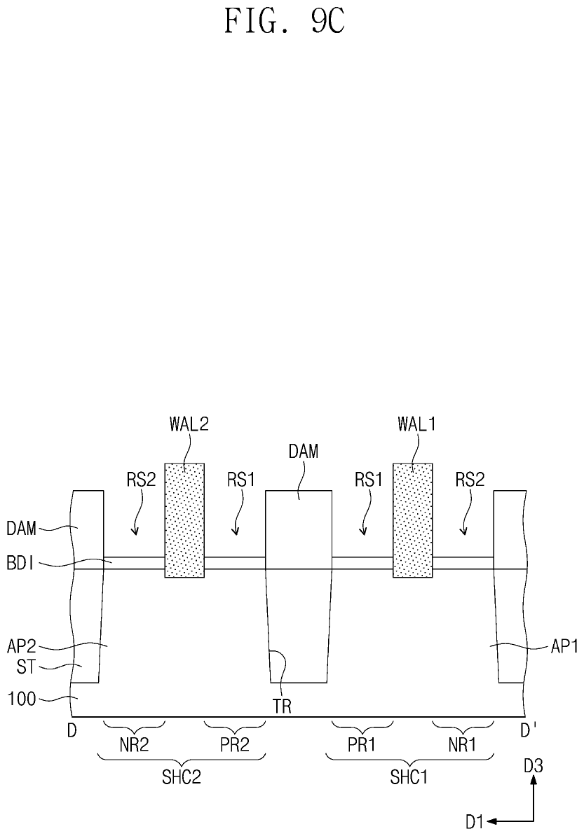

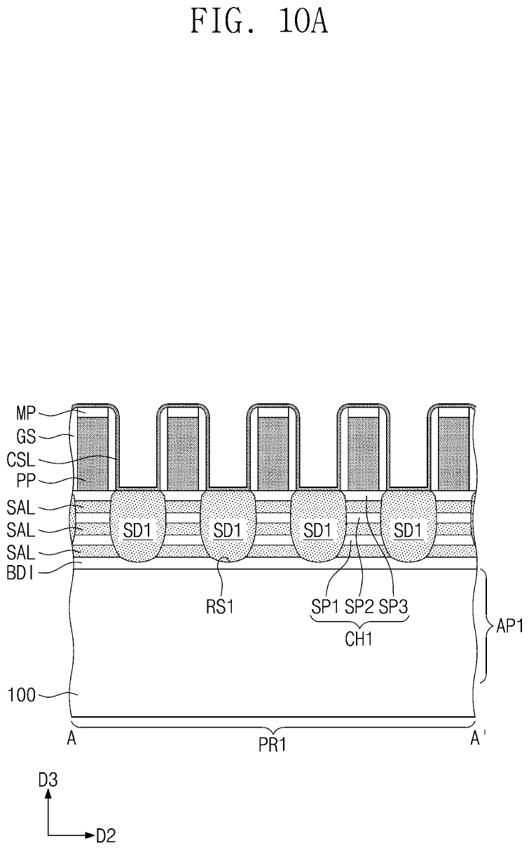

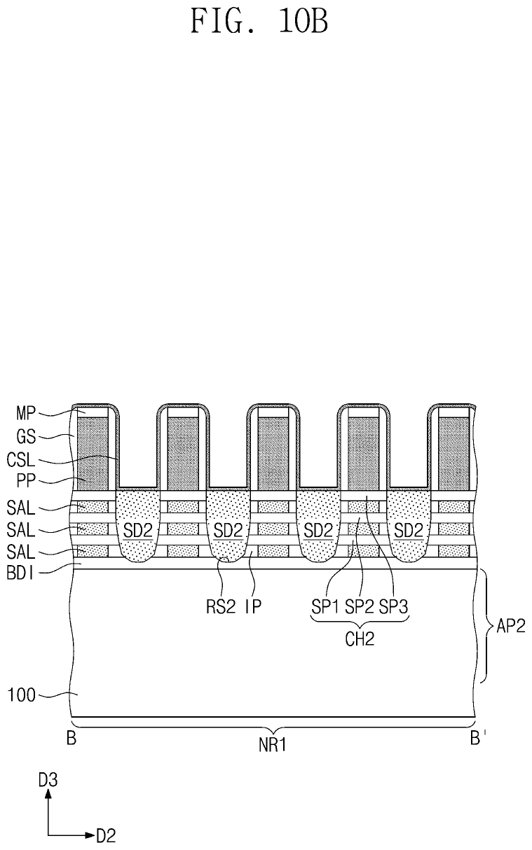

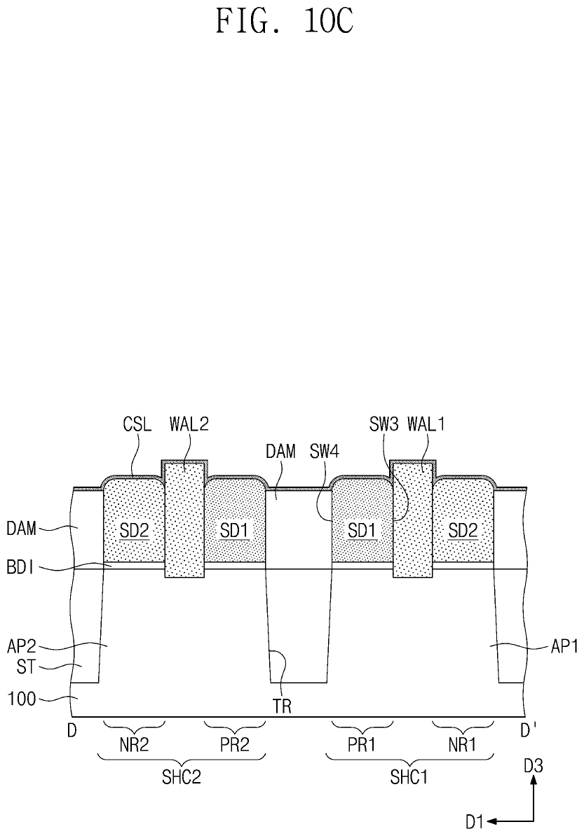

FIGS. 7A to 12C are sectional views illustrating a method of fabricating a semiconductor device, according to an embodiment of the inventive concept. In detail, FIGS. 7A, 8A, 9A, 10A, 11A, and 12A are sectional views corresponding to the line A-A′ of FIG. 4. FIGS. 9B, 10B, 11B, and 12B are sectional views corresponding to the line B-B′ of FIG. 4. FIGS. 9C and 10C are sectional views corresponding to the line D-D′ of FIG. 4. FIGS. 7B, 8B, 11C, and 12C are sectional views corresponding to the line E-E′ of FIG. 4.

Referring to FIGS. 7A and 7B, the substrate 100 including the first and second PMOSFET regions PR1 and PR2 and the first and second NMOSFET regions NR1 and NR2 may be provided. A lowermost sacrificial layer SALL may be formed on the substrate 100. Sacrificial layers SAL and active layers ACL may be alternately formed on the lowermost sacrificial layer SALL. The active and sacrificial layers ACL and SAL may be formed of or include silicon (Si), germanium (Ge), and/or silicon germanium (SiGe), and the active and sacrificial layers ACL and SAL may be formed of different materials from each other.

The sacrificial layer SAL may be formed of or include a material having an etch selectivity with respect to the active layer ACL. For example, the active layers ACL may be formed of or include silicon (Si), and the sacrificial layers SAL may be formed of or include silicon germanium (SiGe). A germanium concentration of each of the sacrificial layers SAL may range from 10 at % to 30 at %. The lowermost sacrificial layer SALL may be formed of or include silicon-germanium (SiGe). However, a germanium concentration of the lowermost sacrificial layer SALL may be higher than the germanium concentration of the sacrificial layer SAL.

Mask patterns may be formed on the first and second PMOSFET regions PR1 and PR2 and the first and second NMOSFET regions NR1 and NR2 of the substrate 100, respectively. The mask pattern may be a line- or bar-shaped pattern that is extended in the second direction D2.

A patterning process using the mask patterns as an etch mask may be performed to form the trench TR defining the first and second active patterns AP1 and AP2. The first active pattern AP1 may be formed on the first PMOSFET region PR1 and the first NMOSFET region NR1. The second active pattern AP2 may be formed on the second PMOSFET region PR2 and the second NMOSFET region NR2.

A stacking pattern STP may be formed on each of the first and second active patterns AP1 and AP2. The stacking pattern STP may include the active layers ACL and the sacrificial layers SAL, which are alternately stacked. The stacking pattern STP may be formed along with the first and second active patterns AP1 and AP2, during the patterning process.

The device isolation layer ST may be formed to at least partially fill the trench TR. In detail, an insulating layer may be formed on the substrate 100 to be on and at least partially cover the first and second active patterns AP1 and AP2 and the stacking patterns STP. The device isolation layer ST may be formed by recessing the insulating layer to expose the stacking patterns STP.

The device isolation layer ST may be formed of or include one or more insulating materials (e.g., silicon oxide). The stacking patterns STP may be exposed to the outside, at a level higher, e.g., in the D3 direction, than the device isolation layer ST. In other words, the stacking patterns STP may be vertically-protruding patterns, which are placed at a level higher, e.g., in the D3 direction, than the device isolation layer ST.

The partition wall WAL1 or WAL2 may be formed to penetrate or extend into the stacking pattern STP. In detail, the first partition wall WAL1 may be formed to penetrate or extend into the stacking pattern STP on the first active pattern AP1. The second partition wall WAL2 may be formed to penetrate or extend into the stacking pattern STP on the second active pattern AP2. Each of the first and second partition walls WAL1 and WAL2 may be formed to penetrate or extend into a center region of the stacking pattern STP. A bottom surface of the partition wall WAL1 or WAL2 may be lower in the D3 direction than the top surface of the active pattern AP1 or AP2.

In detail, the formation of the partition wall WAL1 or WAL2 may include forming a mask layer to have an opening exposing the center region of the stacking pattern STP, anisotropically etching the stacking pattern STP using the mask layer as an etch mask to expose the active pattern AP1 or AP2, at least partially filling the opening of the mask layer with an insulating material, and selectively removing the mask layer.

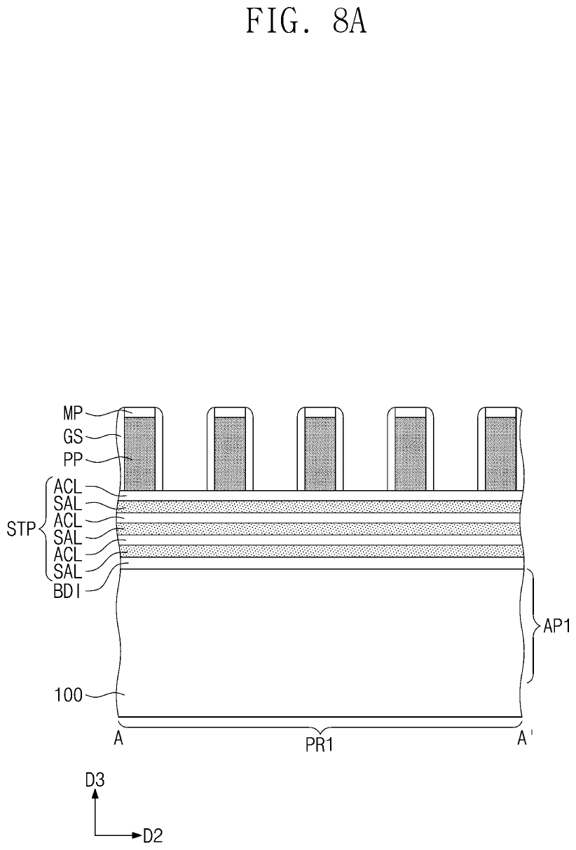

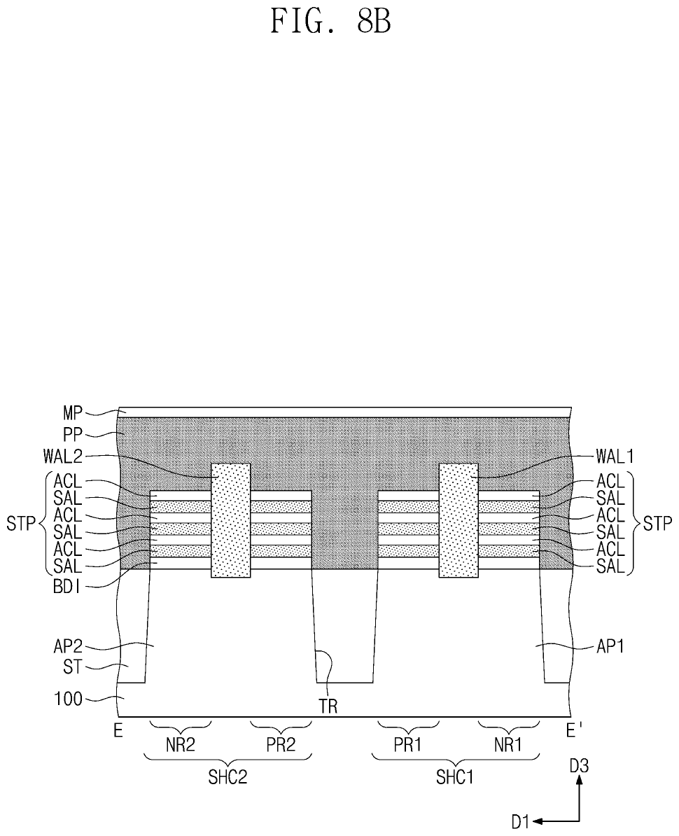

Referring to FIGS. 8A and 8B, sacrificial patterns PP may be formed on the substrate 100 to cross stacking patterns STP. Each of the sacrificial patterns PP may be a line- or bar-shaped pattern extending in the first direction D1. The sacrificial patterns PP may be arranged at a first pitch in the second direction D2.

In detail, the formation of the sacrificial patterns PP may include forming a sacrificial layer on the substrate 100, forming hard mask patterns MP on the sacrificial layer, and patterning the sacrificial layer using the hard mask patterns MP as an etch mask. For example, the sacrificial layer may be formed of or include polysilicon.

The lowermost sacrificial layer SALL, which is exposed between the sacrificial patterns PP, may be selectively removed. A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. In an embodiment, the gate spacer GS may be a multi-layered structure including at least two layers.

Meanwhile, a space, which is formed by removing the lowermost sacrificial layer SALL, may be at least partially filled with an insulating material (i.e., the gate spacer layer), during the formation of the gate spacers GS. As a result, the bottom insulating pattern BDI may be formed between the stacking pattern STP and the active pattern AP1 or AP2. In other words, the bottom insulating pattern BDI and the gate spacer GS may be formed of or include the same insulating material.

Referring to FIGS. 9A to 9C, the dam structure DAM may be formed in a space between the stacking patterns STP, which are adjacent to each other. In an embodiment, the dam structure DAM may be formed to overlap the device isolation layer ST in the D3 direction. The dam structure DAM may be formed to have a line shape extending in the second direction D2. The dam structure DAM may be formed to have a top surface that is located at the same level as a top surface of the stacking pattern STP in the D3 direction.

The dam structure DAM may be formed of or include one or more silicon-based insulating materials (e.g., silicon oxide or silicon nitride). In an embodiment, the dam structure DAM may include a silicon oxide layer. Because the dam structure DAM and the device isolation layer ST include the same materials (e.g., silicon oxide), there may be no visible or observable interface between the dam structure DAM and the device isolation layer ST.

The first recesses RS1 may be formed in the stacking pattern STP on the first and second PMOSFET regions PR1 and PR2. The second recesses RS2 may be formed in the stacking pattern STP on the first and second NMOSFET regions NR1 and NR2. Meanwhile, the dam structure DAM may remain as it is, during the formation of the first and second recesses RS1 and RS2. Thus, the recess RS1 or RS2 may be formed between the dam structure DAM and the partition wall WAL1 or WAL2 (e.g., see FIG. 9C).

In detail, the first recesses RS1 may be formed by etching the stacking pattern STP on the first active pattern AP1 using the hard mask patterns MP and the gate spacers GS as an etch mask. The first recess RS1 may be formed between a pair of the sacrificial patterns PP. Meanwhile, a thickness of the exposed gate spacer GS may be reduced during the etching process (e.g., see GS_U of FIG. 5C). However, a thickness of the gate spacer GS at least partially covered with the dam structure DAM may be unchanged (e.g., see GS_L of FIG. 5C).

The second recesses RS2 in the stacking pattern STP on the second active pattern AP2 may be formed by the same method as that for the first recesses RS1. The formation of the second recess RS2 may further include forming the inner spacers IP in recessed regions that are formed by selectively etching the sacrificial layer SAL.

The first to third semiconductor patterns SP1, SP2, and SP3, which are sequentially stacked between adjacent ones of the first recesses RS1, may be respectively formed from the active layers ACL. The first to third semiconductor patterns SP1, SP2, and SP3, which are sequentially stacked between adjacent ones of the second recesses RS2, may be respectively formed from the active layers ACL. The first to third semiconductor patterns SP1, SP2, and SP3 between adjacent ones of the first recesses RS1 may constitute the first channel pattern CH1. The first to third semiconductor patterns SP1, SP2, and SP3 between adjacent ones of the second recesses RS2 may constitute the second channel pattern CH2.

Referring to FIGS. 10A to 10C, the first source/drain patterns SD1 may be formed in the first recesses RS1, respectively. In detail, the first source/drain pattern SD1 may be grown by performing a first SEG process, in which an inner surface of the first recess RS1 is used as a seed layer.

The first source/drain pattern SD1 may be grown using the first to third semiconductor patterns SP1, SP2, and SP3, which are exposed by the first recess RS1, as a seed layer. In an embodiment, the first SEG process may include a chemical vapor deposition (CVD) process or a molecular beam epitaxy (MBE) process.

The dam structure DAM may inhibit or prevent the first source/drain pattern SD1 from being horizontally, e.g., D1 direction, grown. Thus, the first source/drain pattern SD1 according to the present embodiment may not have a portion that vertically, e.g., D3 direction, overlaps the device isolation layer ST. The third side surface SW3 of the first source/drain pattern SD1 may be in direct contact with the partition wall WAL1 or WAL2, and the fourth side surface SW4 of the first source/drain pattern SD1 may be in direct contact with the dam structure DAM.

During the formation of the first source/drain pattern SD1, the first source/drain pattern SD1 may be doped in-situ with p-type impurities (e.g., boron, gallium, or indium). In other embodiments, impurities may be injected into the first source/drain pattern SD1, after the formation of the first source/drain pattern SD1.

The second source/drain patterns SD2 may be formed in the second recesses RS2, respectively. In detail, the second source/drain pattern SD2 may be formed by a second SEG process, in which an inner surface of the second recess RS2 is used as a seed layer. In an embodiment, the second source/drain pattern SD2 may be formed of or include the same semiconductor material (e.g., Si) as the substrate 100. Meanwhile, the process of forming the second source/drain pattern SD2 may be substantially the same as the afore-described process of forming the first source/drain pattern SD1.

During the formation of the second source/drain pattern SD2, the second source/drain pattern SD2 may be doped in-situ with n-type impurities (e.g., phosphorus, arsenic, or antimony). In other embodiments, impurities may be injected into the second source/drain pattern SD2, after the formation of the second source/drain pattern SD2.

The intermediate insulating pattern CSL may be formed to conformally at least partially cover the dam structures DAM, the first and second source/drain patterns SD1 and SD2, the hard mask patterns MP, and the gate spacers GS. The formation of the intermediate insulating pattern CSL may include performing a deposition process (e.g., a CVD or ALD process). In an embodiment, the intermediate insulating pattern CSL may be formed to directly at least partially cover the top surface of the dam structure DAM.

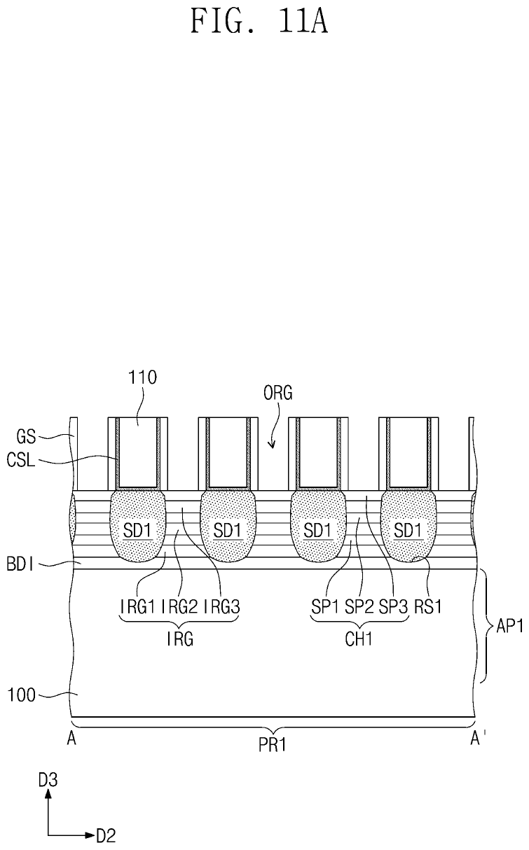

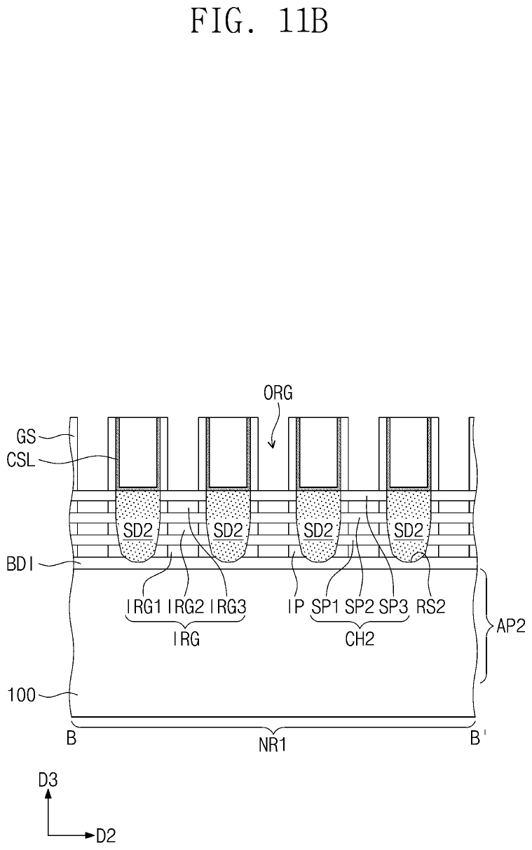

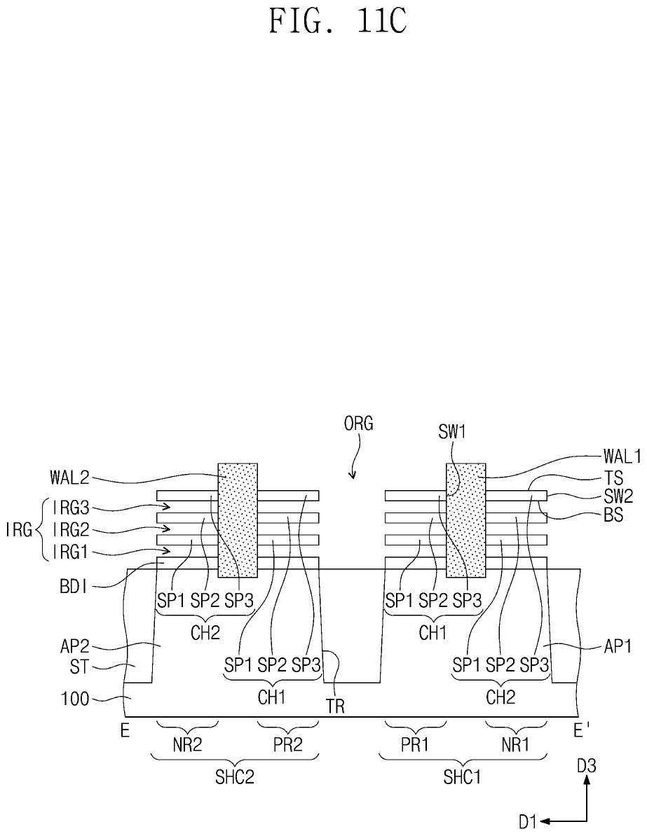

Referring to FIGS. 11A to 11C, the first interlayer insulating layer 110 may be formed on the intermediate insulating pattern CSL. In an embodiment, the first interlayer insulating layer 110 may include a silicon oxide layer. The intermediate insulating pattern CSL may be interposed between the first interlayer insulating layer 110 and the dam structure DAM.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. The hard mask patterns MP may be fully removed during the planarization process. As a result, a top surface of the first interlayer insulating layer 110 may be coplanar with the top surfaces of the sacrificial patterns PP and the top surfaces of the gate spacers GS.

The exposed sacrificial patterns PP may be selectively removed. As a result of the removal of the sacrificial patterns PP, an outer region ORG may be formed to expose the first and second channel patterns CH1 and CH2 (e.g., see FIG. 11C). The removal of the sacrificial patterns PP may include a wet etching process which is performed using an etching solution capable of selectively etching polysilicon.

The sacrificial layers SAL exposed through the outer region ORG may be selectively removed to form inner regions IRG (e.g., see FIG. 11C). In detail, a process of selectively etching the sacrificial layers SAL may be performed to leave the first to third semiconductor patterns SP1, SP2, and SP3 and to remove only the sacrificial layers SAL. The etching process may be chosen to have a high etch rate for a material (e.g., SiGe) having a relatively high germanium concentration. For example, the etching process may be chosen to have a high etch rate for a silicon germanium layer whose germanium concentration is higher than 10 at %.

The sacrificial layers SAL on the first and second PMOSFET regions PR1 and PR2 and the first and second NMOSFET regions NR1 and NR2 may be removed during the etching process. The etching process may be a wet etching process. An etchant material, which is used in the etching process, may be chosen to quickly remove the sacrificial layer SAL having a relatively high germanium concentration. Meanwhile, the first source/drain patterns SD1 on the first and second PMOSFET regions PR1 and PR2 may be protected from the etching process by the buffer layer BFL having a relatively low germanium concentration.

Referring back to FIG. 11C, because the sacrificial layers SAL are selectively removed, only the stacked first to third semiconductor patterns SP1, SP2, and SP3 may be left on each of the first and second active patterns AP1 and AP2. The first to third semiconductor patterns SP1, SP2, and SP3 may be attached to the partition wall WAL1 or WAL2 to have a fork-sheet shape.

Hereinafter, empty regions, which are formed by removing the sacrificial layers SAL, will be referred to as first to third inner regions IRG1, IRG2, and IRG3, respectively. For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

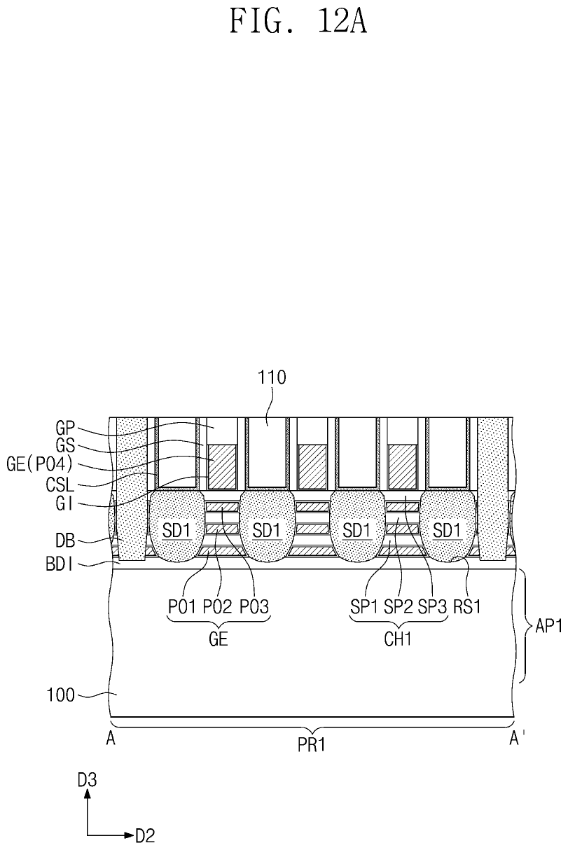

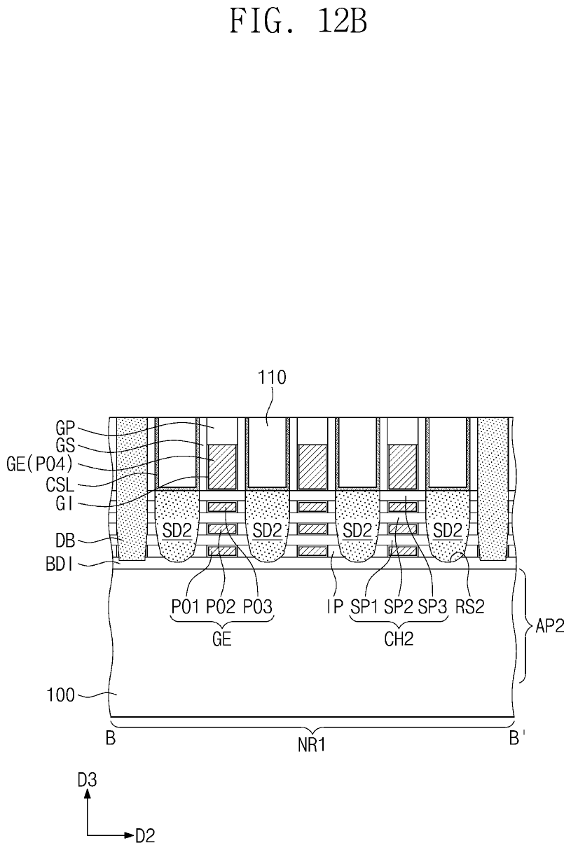

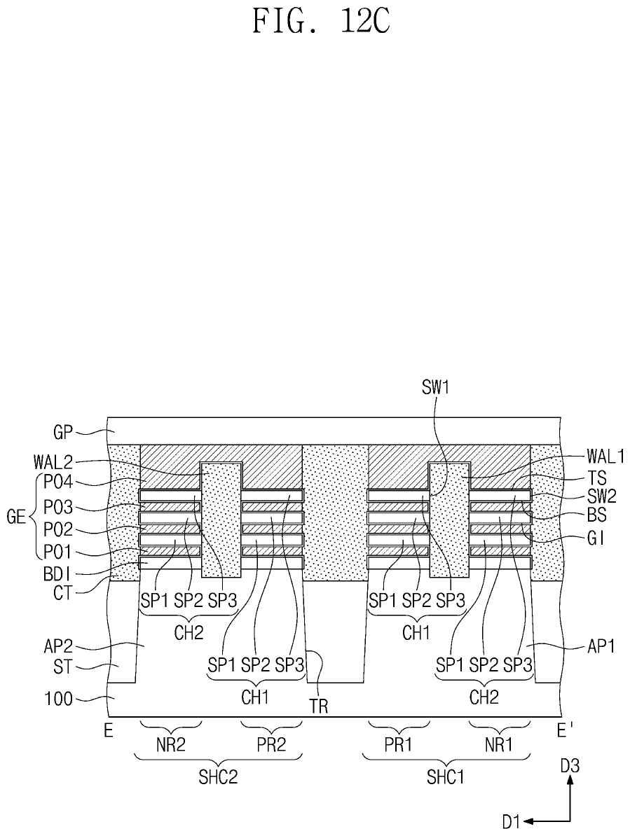

Referring to FIGS. 12A to 12C, the gate insulating layer GI may be conformally formed on the exposed first to third semiconductor patterns SP1, SP2, and SP3. The gate electrode GE may be formed on the gate insulating layer GI. The gate electrode GE may include the first to third inner electrodes PO1, PO2, and PO3, which are respectively formed in the first to third inner regions IRG1, IRG2, and IRG3, and the outer electrode PO4, which is formed in the outer region ORG.

A region of the gate electrode GE may be selectively opened using a photolithography process. For example, regions of the gate electrode GE, which are located on the third and fourth borders BD3 and BD4 of the first single height cell SHC1, may be selectively opened. The opened regions of the gate electrode GE may be selectively removed by an etching process. The gate cutting pattern CT may be formed by at least partially filling a space, which is formed through the selective removal of the gate electrode GE, with an insulating material.

In an embodiment, the gate insulating layer GI may not be etched during the process of etching the gate electrode GE. In an embodiment, the gate insulating layer GI may also be etched during the process of etching the gate electrode GE. In this case, the second side surface SW2 of each of the first to third semiconductor patterns SP1, SP2, and SP3 may be exposed to the outside. The exposed second side surface SW2 may be at least partially covered with the gate cutting pattern CT.

The gate electrode GE may be recessed to have a reduced height. An upper portion of the gate cutting pattern CT may also be recessed, during the process of recessing the gate electrode GE. The gate capping pattern GP may be formed on the recessed gate electrode GE.

The division structure DB may be formed to penetrate or extend into the gate electrode GE. The division structure DB may be provided to penetrate or extend into the gate capping pattern GP and the gate electrode GE and may extend to the bottom insulating pattern BDI. The division structure DB may be formed of or include an insulating material (e.g., silicon oxide or silicon nitride).

Referring back to FIGS. 4 and 5A to 5E, the second interlayer insulating layer 120 may be formed on the first interlayer insulating layer 110. The second interlayer insulating layer 120 may include a silicon oxide layer. The active contacts AC may be formed to penetrate or extend into the second interlayer insulating layer 120, the first interlayer insulating layer 110, and the intermediate insulating pattern CSL and may be electrically connected to the first and second source/drain patterns SD1 and SD2.

The formation of the active contact AC may include forming the barrier metal BM and forming the fill metal FM on the barrier metal BM. The barrier metal BM may be conformally formed and may include a metal layer and a metal nitride layer. The fill metal FM may be formed of or include one or more low resistance metals.

The third interlayer insulating layer 130 may be formed on the second interlayer insulating layer 120. The gate contact GC may be formed to penetrate or extend into the third interlayer insulating layer 130, the second interlayer insulating layer 120, and the gate capping pattern GP and may be connected to the gate electrode GE. The first via VI1 may be formed to penetrate or extend into the third interlayer insulating layer 130 and may be connected to the active contact AC. The gate contact GC and the first via VI1 may be formed together.

The first metal layer M1 may be formed in the third interlayer insulating layer 130. In detail, interconnection lines M1_R1, M1_R2, M1_R3, and M1_I, which are respectively connected to the gate contact GC and the first via VI1, may be formed in an upper portion of the third interlayer insulating layer 130. The fourth interlayer insulating layer 140 may be formed on the third interlayer insulating layer 130. The second metal layer M2 may be formed in the fourth interlayer insulating layer 140.

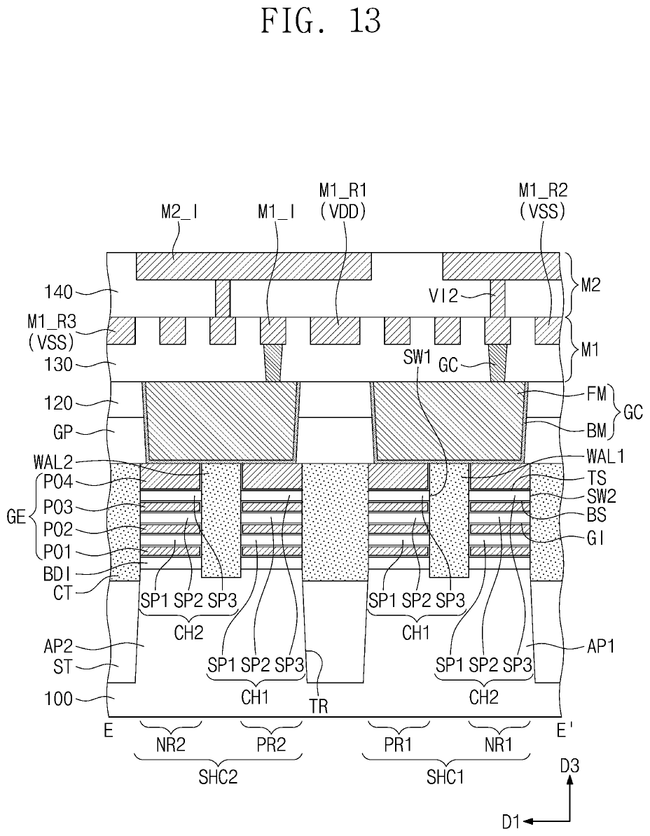

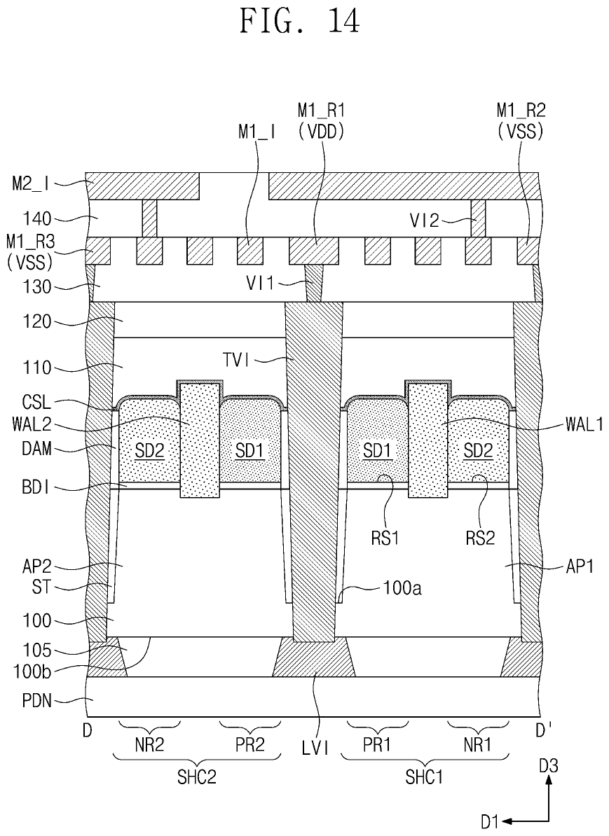

FIG. 13 is a sectional view, which is taken along the line E-E′ of FIG. 4 to illustrate a semiconductor device according to an embodiment of the inventive concept. FIG. 14 is a sectional view, which is taken along the line D-D′ of FIG. 4 to illustrate a semiconductor device according to an embodiment of the inventive concept. FIG. 15 is a sectional view, which is taken along the line E-E′ of FIG. 4 to illustrate a semiconductor device according to an embodiment of the inventive concept. In the following description, an element previously described with reference to FIGS. 4 and 5A to 5E may be identified by the same reference number without repeating an overlapping description thereof.

Referring to FIG. 13, the top surface of the gate electrode GE may be substantially coplanar with a top surface of the partition wall WAL1 or WAL2. The gate electrode GE on the first channel pattern CH1 and the gate electrode GE on the second channel pattern CH2 may be separated from each other with the partition wall WAL1 or WAL2 interposed therebetween. The gate contact GC may be provided on the gate electrode GE on the first channel pattern CH1 and the gate electrode GE on the second channel pattern CH2. The gate contact GC may connect the gate electrode GE on the first channel pattern CH1 to the gate electrode GE on the second channel pattern CH2. The gate contact GC may be electrically connected to the first interconnection line M1_I through the first via VI1. The gate contact GC may include the barrier metal BM and the fill metal FM.

The gate cutting pattern CT may be in direct contact with the first side surface SW1 of each of the first to third semiconductor patterns SP1, SP2, and SP3. That is, the gate insulating layer GI may be omitted from a region between the gate cutting pattern CT and the semiconductor pattern SP1, SP2, or SP3.

Referring to FIG. 14, a penetration via TVI may be provided to penetrate or extend into the dam structure DAM. In an embodiment, a plurality of penetration vias TVI may be electrically connected to the first to third power lines M1_R1, M1_R2, and M1_R3, respectively.

In detail, the penetration via TVI may be vertically, e.g., D3 direction, extended from the second interlayer insulating layer 120 to a bottom surface 100b of the substrate 100. A top surface of the penetration via TVI may be coplanar with a top surface of the second interlayer insulating layer 120. In an embodiment, a bottom surface of the penetration via TVI may be lower than the bottom surface 100b of the substrate 100 in the D3 direction. The first via VI1 may be provided between the penetration via TVI and the power line M1_R1-M1_R3. The penetration via TVI and the power line M1_R1-M1_R3 may be electrically connected to each other through the first via VI1.

A lower insulating layer 105 may be provided on the bottom surface 100b of the substrate 100. Lower conductive structures LVI may be provided in the lower insulating layer 105. Each of the lower conductive structures LVI may be connected to the penetration via TVI. A power delivery network layer PDN may be provided below the lower insulating layer 105 in the cross-sectional view of FIG. 14. The power delivery network layer PDN may include a plurality of lower interconnection lines, which are electrically connected to the lower conductive structures LVI. That is, the power delivery network layer PDN may be electrically connected to the first to third power lines M1_R1, M1_R2, and M1_R3.

In an embodiment, the power delivery network layer PDN may include an interconnection network, which is used to apply the source voltage VSS to the first and third power lines M1_R1 and M1_R3. The power delivery network layer PDN may include an interconnection network, which is used to apply the drain voltage VDD to the second power line M1_R2. In an embodiment, the penetration via TVI and the lower conductive structure LVI may be formed of or include one or more metallic materials including, but not limited to, tungsten (W), molybdenum (Mo), ruthenium (Ru), aluminum (Al), titanium (Ti), and/or tantalum (Ta).

Referring to FIG. 15, the gate cutting pattern CT may be spaced apart from the second side surface SW2 of each of the first to third semiconductor patterns SP1, SP2, and SP3. At least a portion of the outer electrode PO4 may be interposed between the gate cutting pattern CT and the first to third semiconductor patterns SP1, SP2, and SP3. In the present embodiment, the gate electrode GE may be provided to face the top surface TS, the bottom surface BS, and the second side surface SW2 of each of the first to third semiconductor patterns SP1, SP2, and SP3. In this case, the channel controllability of the gate electrode GE may be improved.

In a three-dimensional field effect transistor according to an embodiment of the inventive concept, a dam structure may be used to reduce a cell height of a logic cell. Thus, it may be possible to increase an integration density of the semiconductor device. Furthermore, the gate electrode may have a relatively small length. It may be possible to reduce a parasitic capacitance between the gate electrode and a conductive structure adjacent thereto. As a result, the semiconductor device may have an increased operation speed and improved electric characteristics.

While example embodiments of the inventive concept have been particularly shown and described, it will be understood by one of ordinary skill in the art that variations in form and detail may be made therein without departing from the spirit and scope of the attached claims.

1. A semiconductor device, comprising:
a substrate including an active pattern that is defined by a trench;
a device isolation layer in the trench;
a first source/drain pattern and a second source/drain pattern that are on the active pattern;
a partition wall between the first and second source/drain patterns;
a dam structure and a gate cutting pattern that are on the device isolation layer; and
a gate spacer on a side surface of the gate cutting pattern,
wherein the first source/drain pattern is in a recess between the partition wall and the dam structure,
a lower portion of the gate spacer is interposed between the dam structure and the gate cutting pattern, and
a first thickness of the lower portion of the gate spacer is different from a second thickness of an upper portion of the gate spacer.

2. The semiconductor device of claim 1, wherein the first thickness is larger than the second thickness.

3. The semiconductor device of claim 1, wherein the first source/drain pattern comprises a first side surface and a second side surface, which are opposite to each other,
the first side surface is in contact with the partition wall, and
the second side surface is in contact with the dam structure.

4. The semiconductor device of claim 1, further comprising:
a first channel pattern and a second channel pattern that are on the active pattern; and
a gate electrode on the first and second channel patterns,
wherein the partition wall is interposed between the first and second channel patterns, and
the gate cutting pattern extends into the gate electrode.

5. The semiconductor device of claim 4, wherein the first channel pattern comprises a plurality of semiconductor patterns, which are spaced apart from each other in a stack,
each of the semiconductor patterns has a first side surface and a second side surface, which are opposite to each other,
the first side surface is connected to the partition wall, and
the gate cutting pattern is on the second side surface.

6. The semiconductor device of claim 5, further comprising a gate insulating layer between the semiconductor patterns and the gate electrode,
wherein the gate insulating layer is interposed between the second side surface and the gate cutting pattern.

7. The semiconductor device of claim 1, further comprising:
an interlayer insulating layer on the dam structure; and
an intermediate insulating pattern between the dam structure and the interlayer insulating layer.

8. The semiconductor device of claim 1, further comprising at least one active contact connected to the first and second source/drain patterns,
wherein a bottom surface of the active contact is between a top surface of the dam structure and an upper surface of the substrate.

9. The semiconductor device of claim 1, wherein a top surface of the dam structure is between a top surface of each of the first and second source/drain patterns and an upper surface of the substrate.

10. The semiconductor device of claim 1, further comprising a bottom insulating pattern interposed between each of the first and second source/drain patterns and the active pattern,
wherein the bottom insulating pattern extends from the partition wall to the dam structure.

11. A semiconductor device, comprising:
a substrate including an active pattern that is defined by a trench;
a device isolation layer in the trench;
a first channel pattern and a second channel pattern that are on the active pattern;
a partition wall between the first and second channel patterns;
a gate electrode on the first and second channel patterns; and
a gate cutting pattern on the device isolation layer,
wherein the gate cutting pattern extends into the gate electrode,
the first channel pattern comprises a plurality of semiconductor patterns, which are spaced apart from each other in a stack,
each of the semiconductor patterns has a first side surface and a second side surface, which are opposite to each other,
the first side surface is connected to the partition wall, and
the gate cutting pattern is on the second side surface.

12. The semiconductor device of claim 11, wherein the gate electrode comprises an inner electrode, which is between adjacent ones of the semiconductor patterns, and an outer electrode, which is on an uppermost one of the semiconductor patterns relative to an upper surface of the substrate being a base reference surface.

13. The semiconductor device of claim 11, further comprising a gate insulating layer between the semiconductor patterns and the gate electrode,
wherein the gate insulating layer is interposed between the second side surface and the gate cutting pattern.

14. The semiconductor device of claim 11, wherein the gate cutting pattern is in direct contact with the second side surface.

15. The semiconductor device of claim 11, further comprising a bottom insulating pattern interposed between the gate electrode and the active pattern,
wherein the bottom insulating pattern extends from the partition wall to the gate cutting pattern.

16. A semiconductor device, comprising:
a substrate including a first active pattern and a second active pattern;
a device isolation layer in a trench between the first and second active patterns;
a first source/drain pattern and a second source/drain pattern that are on the first active pattern;
a third source/drain pattern and a fourth source/drain pattern that are on the second active pattern, the first and third source/drain patterns having a first conductivity type, the second and fourth source/drain patterns having a second conductivity type, the first source/drain pattern being adjacent to the third source/drain pattern;
a first partition wall and a second partition wall on the first and second active patterns, respectively, the first partition wall being interposed between the first and second source/drain patterns, the second partition wall being interposed between the third and fourth source/drain patterns;
a dam structure on the device isolation layer, the dam structure being interposed between the first source/drain pattern and the third source/drain pattern;
an intermediate insulating pattern on a top surface of the dam structure and top surfaces of the first and second partition walls;
an interlayer insulating layer on the intermediate insulating pattern;
active contacts that extend into the interlayer insulating layer and are coupled to the first to fourth source/drain patterns; and
a first metal layer on the active contacts,
wherein the first metal layer comprises a power line, and
wherein the power line overlaps the dam structure in a direction perpendicular to an upper surface of the substrate.

17. The semiconductor device of claim 16, wherein a bottom surface of each of the active contacts is between the top surface of the dam structure and the upper surface of the substrate.

18. The semiconductor device of claim 16, wherein the top surface of the dam structure is between a top surface of each of the first to fourth source/drain patterns and the upper surface of the substrate.

19. The semiconductor device of claim 16, wherein the top surface of the dam structure is between the top surfaces of the first and second partition walls and the upper surface of the substrate.

20. The semiconductor device of claim 16, further comprising:
a penetration via extending through the interlayer insulating layer, the intermediate insulating pattern, the dam structure, the device isolation layer, and the substrate; and
a power delivery network layer on a bottom surface of the substrate,
wherein the penetration via electrically connects the power delivery network layer and the power line to each other.

21-25. (canceled)
